(19) United States
(12) Patent Application Publication
(10) Pub. No.: US 2024/0339425 A1
(43) Pub. Date: Oct. 10, 2024

(54) SEMICONDUCTOR DEVICE

(71) Applicant: Murata Manufacturing Co., Ltd., Kyoto-fu (JP)

(72) Inventors: Mari SAJI, Nagaokakyo-shi (JP); Atsushi KUROKAWA, Nagaokakyo-shi (JP); Masahiro SHIBATA, Nagaokakyo-shi (JP)

(73) Assignee: Murata Manufacturing Co., Ltd., Kyoto-fu (JP)

(21) Appl. No.: 18/750,258

(22) Filed: Jun. 21, 2024

Related U.S. Application Data
(63) Continuation of application No. PCT/JP2022/046949, filed on Dec. 20, 2022.

(30) Foreign Application Priority Data
Jan. 7, 2022 (JP) 2022-001852

(51) Int. Cl. H01L 23/00

(52) U.S. Cl. CPC H01L 24/13; H01L 2224/13014; H01L 2224/13024; H01L 2224/13124; H01L 2224/13144; H01L 2224/13147; H01L 2924/10329; H01L 2924/10338; H01L 2924/13051; H01L 2924/3512

(57) ABSTRACT

A semiconductor device includes a semiconductor substrate, at least one transistor on the semiconductor substrate and including semiconductor layers, a wiring on the transistor, a first insulating film including a first opening in a region overlapping the transistor and the wiring in plan view in a first direction perpendicular to the semiconductor substrate, a first redistribution layer on the first insulating film, overlapping the at least one transistor in the first direction in plan view, and electrically connected to the wiring via the first opening, a second insulating film covering the first redistribution layer and the first insulating film and provided with a second opening in a region overlapping at least a part of the first redistribution layer in the first direction in plan view, and a bump electrically connected to the first redistribution layer via the second opening.

### CROSS-REFERENCE TO RELATED APPLICATIONS

This application claims benefit of priority to International Patent Application No. PCT/JP2022/046949, filed Dec. 20, 2022, and to Japanese Patent Application No. 2022-001852, filed Jan. 7, 2022, the entire contents of each are incorporated herein by reference.

### BACKGROUND

### Technical Field

The present disclosure relates to a semiconductor device.

### Background Art

Japanese Unexamined Patent Application Publication No. 2019-149485 describes a semiconductor device including a heterojunction bipolar transistor. The semiconductor device described in Japanese Unexamined Patent Application Publication No. 2019-149485 includes a bump provided directly above a transistor. The bump is electrically connected to an emitter electrode of the transistor via an opening of an organic insulating film (resin film) covering the transistor.

### SUMMARY

When the bump is provided to overlap the entire region of a mesa structure of the transistor, heat dissipation is improved (that is, thermal resistance is reduced), but the reliability of the semiconductor device may be reduced, for example, a crack may be generated in the mesa structure due to stress from the bump.

Accordingly, the present disclosure provides a semiconductor device capable of suppressing stress generated in a transistor.

A semiconductor device according to an aspect of the present disclosure includes a semiconductor substrate, at least one transistor provided on the semiconductor substrate and including a plurality of semiconductor layers, a wiring provided on the transistor, a first insulating film provided with a first opening in a region overlapping the transistor and the wiring in plan view in a first direction perpendicular to the semiconductor substrate, and a first redistribution layer provided on the first insulating film, overlapping the at least one transistor in the first direction in plan view, and electrically connected to the wiring via the first opening. The semiconductor device further includes a second insulating film provided to cover the first redistribution layer and the first insulating film, and provided with a second opening in a region overlapping at least a part of the first redistribution layer in the first direction in plan view, and a bump electrically connected to the first redistribution layer via the second opening, in which a width of the first opening of the first insulating film in a second direction parallel to the semiconductor substrate is larger than a width of the second opening of the second insulating film in the second direction.

According to the semiconductor device of the present disclosure, stress generated in a transistor can be suppressed.

### BRIEF DESCRIPTION OF THE DRAWINGS

FIG. 1 is a plan view of a semiconductor device according to a first embodiment;

FIG. 2 is a cross-sectional view taken along line II-II′ in FIG. 1.

FIG. 3 is a table for explaining the relationship between the opening width and the presence or absence of defect occurrence in semiconductor devices according to an example and a comparative example;

FIG. 4 is a cross-sectional view of a semiconductor device according to a second embodiment;

FIG. 5 is a cross-sectional view of a semiconductor device according to a third embodiment;

FIG. 6 is an explanatory view of a semiconductor device according to a modification of the third embodiment; and

FIG. 7 is an explanatory view for explaining a manufacturing process of a semiconductor device.

### DETAILED DESCRIPTION

Hereinafter, embodiments of a semiconductor device of the present disclosure will be described in detail with reference to the drawings. Note that the present disclosure is not limited to the embodiments. Each embodiment is an example, and it is needless to say that partial replacement or combination of configurations shown in different embodiments is possible. In a second and subsequent embodiments, the description of matters common to a first embodiment will be omitted, and only different points will be described. In particular, similar effects of similar configurations will not be described in each embodiment.

### First Embodiment

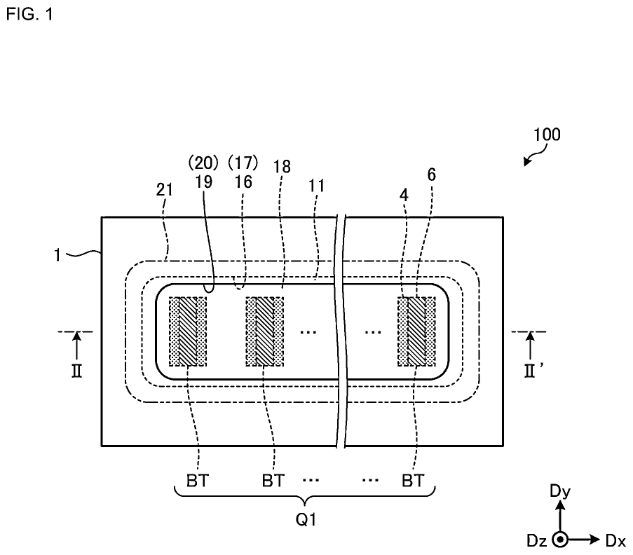

FIG. 1 is a plan view of a semiconductor device according to the first embodiment. Note that FIG. 1 schematically illustrates an arrangement relationship between a mesa structure including a base layer 4 of each transistor and an emitter electrode 6, while omitting the detailed configuration of each transistor BT. In addition, in FIG. 1, a bump 21 is indicated by a two-dot-dash line for easy understanding of the drawing.

As illustrated in FIG. 1, a semiconductor device 100 includes a semiconductor substrate 1, a transistor group Q1, a first organic insulating film 16, a second organic insulating film 19, an emitter wiring 11, a first redistribution layer 18, and the bump 21.

In the following description, one direction in a plane parallel to the surface of the semiconductor substrate 1 is referred to as an X-axis direction Dx. In addition, a direction orthogonal to the X-axis direction Dx in a plane parallel to the surface of the semiconductor substrate 1 is referred to as a Y-axis direction Dy. In addition, a direction orthogonal to each of the X-axis direction Dx and the Y-axis direction Dy is referred to as a Z-axis direction Dz. The Z-axis direction Dz is a direction perpendicular to the surface of the semiconductor substrate 1. The Z-axis direction Dz is an example of a “first direction”, and the X-axis direction Dx and the Y-axis direction Dy are an example of a “second direction”. In addition, in the present specification, the plan view indicates a positional relationship when viewed from the Z-axis direction Dz.

A transistor group Q1 is provided on the surface of the semiconductor substrate 1. The transistor group Q1 includes a plurality of transistors BT. The transistor BT is a heterojunction bipolar transistor (HBT). The transistor BT is also referred to as a unit transistor, and the unit transistor is defined as the smallest transistor constituting the transistor group Q1. The transistors BT are electrically connected in parallel to constitute the transistor group Q1.

The plurality of transistors BT of the transistor group Q1 are arranged side by side in the X-axis direction Dx. The mesa structure including the base layer 4 of each of the plurality of transistors BT and the emitter electrode 6 each extend in the Y-axis direction Dy.

In FIG. 1, the transistor group Q1 is configured to include three or more transistors BT. However, the number and arrangement of the transistors BT are just an example and can be changed as appropriate. At least one transistor BT is provided. In addition, although one transistor group Q1 is illustrated in FIG. 1 for the sake of easy understanding, two or more transistor groups may be provided on the same semiconductor substrate 1.

The first redistribution layer 18 and the bump 21 overlap the plurality of transistors BT of the transistor group Q1 in plan view. The first redistribution layer 18 is electrically connected to the emitter wiring 11 via a first opening 17 provided in the first organic insulating film 16.

The bump 21 is electrically connected to the first redistribution layer 18 via a second opening 20 provided in the second organic insulating film 19. Thus, the bump 21 is electrically connected to the plurality of transistors BT via the first redistribution layer 18. The bump 21 has an oval shape in plan view, extends in the X-axis direction Dx, and is provided along the arrangement direction of the plurality of transistors BT. The bump 21 is provided to cover the entire plurality of transistors BT arranged in the X-axis direction Dx. In addition, the width of the bump 21 in the Y-axis direction Dy is larger than the width of the mesa structure including the base layer 4 of the plurality of transistors BT and the emitter electrode 6 in the Y-axis direction Dy.

Note that the detailed relationship between the first redistribution layer 18, the bump 21, the first opening 17 provided in the first organic insulating film 16, and the second opening 20 provided in the second organic insulating film 19 will be described later.

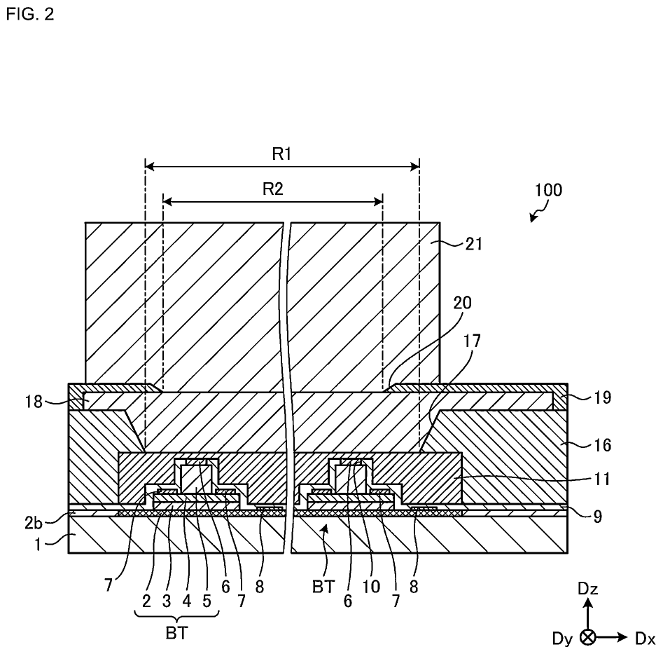

Next, a detailed cross-sectional configuration of the semiconductor device 100 will be described. FIG. 2 is a cross-sectional view taken along line II-II′ in FIG. 1. As illustrated in FIG. 2, in the semiconductor device 100, the transistor BT includes a sub-collector layer 2, a collector layer 3, the base layer 4, an emitter layer 5, the emitter electrode 6, a base electrode 7, and a collector electrode 8. The transistor BT is formed by stacking the sub-collector layer 2, the collector layer 3, the base layer 4, the emitter layer 5, and the emitter electrode 6 in this order on the semiconductor substrate 1. In addition, the base electrode 7 is provided on the base layer 4, and the collector electrode 8 is provided on the sub-collector layer 2.

The mesa structure of the present embodiment is formed of one or a plurality of the semiconductor layers (the sub-collector layer 2, the collector layer 3, the base layer 4, and the emitter layer 5) included in the transistor BT. For example, the mesa structure is a collector mesa including the collector layer 3 and the base layer 4.

More specifically, the semiconductor substrate 1 is, for example, a semi-insulating gallium arsenide (GaAs) substrate. The sub-collector layer 2 is provided on the semiconductor substrate 1. The sub-collector layer 2 is a high concentration n-type GaAs layer, and has a thickness of, for example, about 0.5 μm. The collector layer 3 is provided on the sub-collector layer 2. The collector layer 3 is an n-type GaAs layer and has a thickness of, for example, about 1 μm. The base layer 4 is provided on the collector layer 3. The base layer 4 is a p-type GaAs layer and has a thickness of, for example, about 100 nm.

The emitter layer 5 is provided on the base layer 4. Although not illustrated, the emitter layer 5 includes, for example, an intrinsic emitter layer and an emitter mesa layer provided thereon from the base layer 4 side. The intrinsic emitter layer is an n-type indium gallium phosphide (InGaP) layer, and has a thickness of, for example, equal to or more than 30 nm and equal to or less than 40 nm (i.e., from 30 nm to 40 nm). The emitter mesa layer is formed of a high concentration n-type GaAs layer and a high concentration n-type InGaAs layer. The thicknesses of the high concentration n-type GaAs layer and the high concentration n-type InGaAs layer are each, for example, about 100 nm. The high concentration n-type InGaAs layer of the emitter mesa layer is provided for ohmic contact with the emitter electrode 6.

The base layer 4 and the collector layer 3 are epitaxially grown on the semiconductor substrate 1, and then subjected to etching processing to form a mesa structure. Note that the mesa structure may be formed by the base layer 4 and the upper portion of the collector layer 3 without removing the lower portion of the collector layer 3.

The collector electrode 8 is provided on the sub-collector layer 2 in contact with the sub-collector layer 2. The collector electrode 8 is arranged adjacent to, for example, the mesa structure (the base layer 4 and the collector layer 3) in the X-axis direction Dx. The collector electrode 8 has a stacked film in which, for example, a gold germanium (AuGe) film, a nickel (Ni) film, and a gold (Au) film are stacked in this order. The thickness of the AuGe film is, for example, 60 nm. The thickness of the Ni film is, for example, 10 nm. The thickness of the Au film is, for example, 200 nm.

The base electrode 7 is provided on the base layer 4 in contact with the base layer 4. The base electrode 7 is a stacked film in which a Ti film, a Pt film, and an Au film are stacked in this order. The thickness of the Ti film is, for example, 50 nm. The thickness of the Pt film is, for example, 50 nm. The thickness of the Au film is, for example, 200 nm.

The emitter electrode 6 is provided on the emitter layer 5 in contact with the emitter layer 5. The emitter electrode 6 is a titanium (Ti) film. The thickness of the Ti film is, for example, 50 nm.

Note that an isolation region 2b is provided adjacent to the sub-collector layer 2 on the semiconductor substrate 1. The isolation region 2b is insulated by an ion implantation technique. The isolation region 2b provides insulation between elements (between the plurality of transistors BT).

An inorganic insulating film 9 is provided on the sub-collector layer 2 and the isolation region 2b while covering the plurality of transistors BT except a part of the emitter electrode 6. The inorganic insulating film 9 is, for example, a silicon nitride (SiN) layer. The inorganic insulating film 9 may be a single layer or may be formed by stacking a plurality of nitride layers or oxide layers.

The emitter wiring 11 is provided on the inorganic insulating film 9 to cover the plurality of transistors BT. An emitter opening 10 is provided in a region of the inorganic insulating film 9 overlapping the emitter electrode 6 in plan view, and the emitter wiring 11 is electrically connected to the emitter electrode 6 in the emitter opening 10.

The first organic insulating film 16 is provided on the inorganic insulating film 9 to cover a part of the emitter wiring 11. The first organic insulating film 16 is an organic protective film made of an organic material such as polyimide or BCB, for example. The first organic insulating film 16 is provided with the first opening 17 in a region overlapping the plurality of transistors BT, the emitter electrode 6, and the emitter wiring 11 in plan view.

The first redistribution layer 18 is provided on the first organic insulating film 16, overlaps the plurality of transistors BT, and is electrically connected to the emitter wiring 11 via the first opening 17.

The second organic insulating film 19 is provided on the first organic insulating film 16 to cover a part of the first redistribution layer 18. The second opening 20 is provided in a region of the second organic insulating film 19 overlapping the first redistribution layer 18 in plan view. The bump 21 is provided in a region overlapping the second opening 20 and is electrically connected to the first redistribution layer 18 via the second opening 20. With such a configuration, the bump 21 is electrically connected to the emitter electrodes 6 of the plurality of transistors BT via the first opening 17 and the second opening 20. The bump 21 is a pillar bump and is made of, for example, copper (Cu). The bump 21 is made of a metal material having a low resistance such as aluminum (Al) or gold (Au), in addition to Cu.

Note that although not illustrated in FIG. 2, a metal film such as a diffusion prevention layer or a seed layer for plating may be provided between the bump 21 and the first redistribution layer 18. As the diffusion prevention layer and the seed layer, for example, a material such as nickel (Ni), titanium (Ti), tungsten (W), or chromium (Cr) is used.

A width R1 of the first opening 17 of the first organic insulating film 16 in the X-axis direction Dx is larger than a width R2 of the second opening 20 of the second organic insulating film 19 in the X-axis direction Dx. In other words, in plan view, the inner peripheral surface of the second organic insulating film 19 forming the second opening 20 is formed in a region inside the inner peripheral surface of the first organic insulating film 16 forming the first opening 17 (see FIG. 1).

Here, the width R1 of the first opening 17 of the first organic insulating film 16 is defined as a distance in the X-axis direction Dx at positions where the inner peripheral surface of the first organic insulating film 16 forming the first opening 17 is in contact with the emitter wiring 11 on the semiconductor substrate 1 side. Similarly, the width R2 of the second opening 20 of the second organic insulating film 19 is defined as a distance in the X-axis direction Dx at positions where the inner peripheral surface of the second organic insulating film 19 forming the second opening 20 is in contact with the first redistribution layer 18 on the semiconductor substrate 1 side.

In addition, the width of the bump 21 provided on the second organic insulating film 19 in the X-axis direction Dx is larger than the width R1 of the first opening 17 and the width R2 of the second opening 20. The bump 21 is in contact with the first redistribution layer 18 at the bottom of the second opening 20. As described above, the first opening 17 is formed to have the width R1 larger than the width R2 of the second opening 20. In other words, the width in the X-axis direction Dx of the portion where the bump 21 and the first redistribution layer 18 are in contact with each other in the second opening 20 (the width R2 of the second opening 20) is smaller than the width R1 of the first opening 17.

Note that the width of the bump 21 in the X-axis direction Dx on the second organic insulating film 19 is not particularly limited and can be changed as appropriate. For example, the width of the bump 21 in the X-axis direction Dx may be larger than the width R2 of the second opening 20 and smaller than the width R1 of the first opening 17.

As described above, the semiconductor device 100 of the present embodiment includes the semiconductor substrate 1, at least one transistor BT provided on the semiconductor substrate 1 and including a plurality of semiconductor layers, the emitter wiring 11 (wiring) provided on the transistor BT, the first organic insulating film 16 (first insulating film) provided with the first opening 17 in the region overlapping the transistor BT and the emitter wiring 11, the first redistribution layer 18 provided on the first organic insulating film 16, overlapping the at least one transistor BT in plan view, and electrically connected to the emitter wiring 11 via the first opening 17, the second organic insulating film 19 (second insulating film) provided to cover the first redistribution layer 18 and the first organic insulating film 16 and provided with the second opening 20 in the region overlapping at least a part of the first redistribution layer 18, and the bump 21 electrically connected to the first redistribution layer 18 via the second opening 20. The width R1 of the first opening 17 of the first organic insulating film 16 in the X-axis direction Dx parallel to the semiconductor substrate 1 is larger than the width R2 of the second opening 20 of the second organic insulating film 19 in the X-axis direction Dx.

Thus, in the semiconductor device 100, the bump 21 is provided to cover the entire region of the mesa structure of the plurality of transistors BT, and the heat dissipation can be improved. In addition, thermal stress generated when the semiconductor device 100 is mounted on an external substrate such as a printed wiring substrate is applied to the mesa structure of the plurality of transistors BT from the bump 21. In the present embodiment, the width R1 of the first opening 17 of the first organic insulating film 16 in the X-axis direction Dx is formed to be larger than the width R2 of the second opening 20 of the second organic insulating film 19 in the X-axis direction Dx. Therefore, even when stress is concentrated on the outer edge side of the bump 21 (a portion of the bump 21 in contact with the inner peripheral surface of the second organic insulating film 19), the stress transmitted from the bump 21 to the first redistribution layer 18 is dispersed in a region of the first redistribution layer 18 overlapping the first opening 17. That is, the concentration of stress on the outer edge side of the first redistribution layer 18 (a portion of the first redistribution layer 18 in contact with the inner peripheral surface of the first organic insulating film 16) is suppressed. As a result, in the present embodiment, it is possible to suppress thermal stress applied to the mesa structure of the transistor BT from the bump 21 via the first redistribution layer 18.

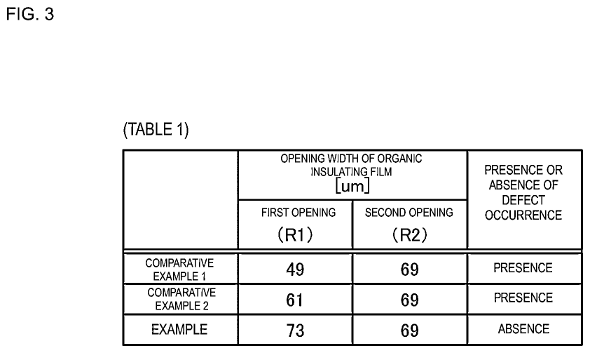

FIG. 3 is a table for explaining the relationship between the opening width and the presence or absence of defect occurrence in the semiconductor devices according to the example and the comparative example. As illustrated in FIG. 3, Comparative Examples 1 and 2 are semiconductor devices each having the configuration in which the width R1 of the first opening 17 is formed to be smaller than the width R2 of the second opening 20. Specifically, in the semiconductor device of Comparative Example 1, the width R1 of the first opening 17 is 49 μm, and the width R2 of the second opening 20 is 69 μm. In the semiconductor device of Comparative Example 2, the width R1 of the first opening 17 is 61 μm, and the width R2 of the second opening 20 is 69 μm. In the semiconductor device 100 of Example, the width R1 of the first opening 17 is 73 μm, and the width R2 of the second opening 20 is 69 μm.

In each of the semiconductor devices of Comparative Examples 1 and 2, a crack is generated in the mesa structure of the transistor BT. More specifically, Comparative Examples 1 and 2 have a configuration in which the width R1 of the first opening 17 is smaller than the width R2 of the second opening 20, that is, the outer edge side of the bump 21 provided in the second opening 20 (the portion of the bump 21 in contact with the inner peripheral surface of the second organic insulating film 19) is located in an outer side portion of the first opening 17. The stress from the bump 21 reaches the mesa structure of the transistor BT mainly through the hard material. That is, since the first organic insulating film 16 and the second organic insulating film 19 have a small Young's modulus compared with the metal material of the first redistribution layer 18 and the like, most of the thermal stress is concentrated on the wiring portions of the first redistribution layer 18 and the emitter wiring 11 and is transmitted to the mesa structure of the transistor BT. Therefore, the stress from the bump 21 is concentrated on the outer edge side of the bump 21 (the portion of the bump 21 in contact with the inner peripheral surface of the second organic insulating film 19), and further concentrated on the outer edge side of the first redistribution layer 18 (the portion of the first redistribution layer 18 in contact with the inner peripheral surface of the first organic insulating film 16) to be transmitted to the transistor BT side. As a result, in Comparative Examples 1 and 2, thermal stress is concentrated on a part of the mesa structure of the transistor BT, and a crack is generated in the mesa structure of the transistor BT.

In the semiconductor device 100 of Example, no crack is generated in the mesa structure of the transistor BT. The semiconductor device 100 of Example is configured such that the first opening 17 is formed to have the width R1 larger than the width R2 of the second opening 20, and as described above, the stress transmitted from the bump 21 to the first redistribution layer 18 is dispersed in the region of the first redistribution layer 18 overlapping the first opening 17. As described above, it is shown that the semiconductor device 100 of Example can suppress the concentration of stress as described in Comparative Examples 1 and 2 and can suppress the occurrence of cracks in the mesa structure of the transistor BT.

### Second Embodiment

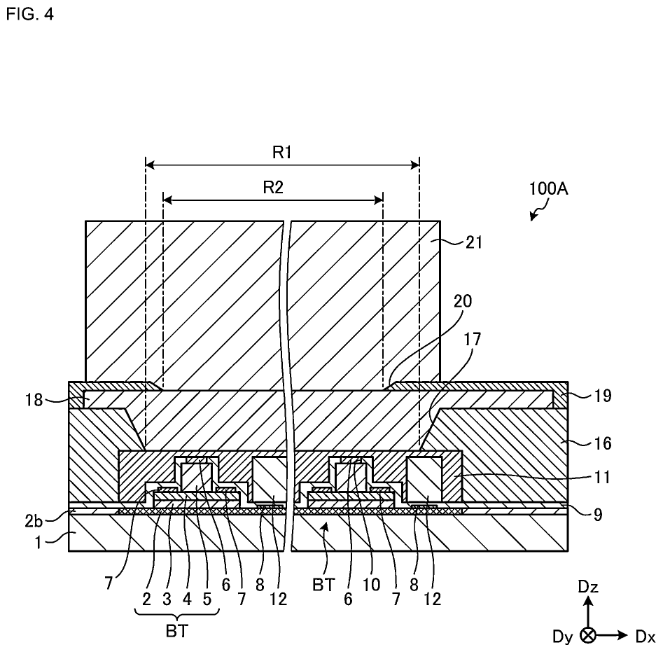

FIG. 4 is a cross-sectional view of a semiconductor device according to a second embodiment. As illustrated in FIG. 4, in the second embodiment, a configuration having an overlapping organic insulating film 12 provided between the collector electrode 8 and the emitter wiring 11 and the first redistribution layer 18 in a direction perpendicular to the semiconductor substrate 1, which is different from the above-described first embodiment, will be described. Note that the configurations of the plurality of transistors BT, the first opening 17 of the first organic insulating film 16, the second opening 20 of the second organic insulating film 19, and the like are the same as those of the first embodiment, and thus the repeated description thereof will be omitted.

In a semiconductor device 100A according to the second embodiment, the overlapping organic insulating film 12 is provided to overlap the collector electrode 8 of the transistor BT. The inorganic insulating film 9, the overlapping organic insulating film 12, the emitter wiring 11, and the first redistribution layer 18 are stacked in this order on the collector electrode 8. In the present embodiment, since the overlapping organic insulating film 12 is provided, insulation between the collector and the emitter can be secured.

The overlapping organic insulating film 12 is provided in a region that does not overlap the mesa structure formed of the collector layer 3, the base layer 4, and the emitter layer 5 in plan view. In this case, when attention is paid to the emitter wiring 11 and the overlapping organic insulating film 12, since the overlapping organic insulating film 12 has a smaller Young's modulus than the emitter wiring 11, most of the thermal stress is concentrated on the emitter wiring 11 in a portion where the overlapping organic insulating film 12 is not provided, and there is a possibility that a larger stress is transmitted to the mesa structure of the transistor BT.

In the present embodiment as well, the width R1 of the first opening 17 of the first organic insulating film 16 in the X-axis direction Dx is larger than the width R2 of the second opening 20 of the second organic insulating film 19 in the X-axis direction Dx. As such, the concentration of stress transmitted from the bump 21 to the emitter wiring 11 via the first redistribution layer 18 is suppressed. Therefore, even in the configuration in which the overlapping organic insulating film 12 is provided on the collector electrode 8, it is possible to suppress the concentration of stress on the mesa structure of the transistor BT, and to suppress the occurrence of cracks.

Note that the shape, thickness, and the like of the overlapping organic insulating film 12 illustrated in FIG. 4 are merely schematically shown, and can be appropriately changed according to the configurations of the collector electrode 8 and the emitter wiring 11, and the required insulating characteristics.

### Third Embodiment

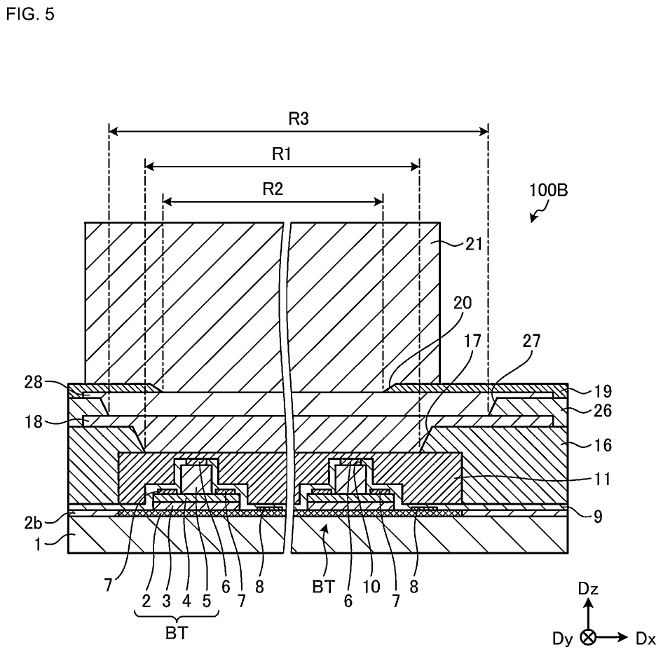

FIG. 5 is a cross-sectional view of a semiconductor device according to a third embodiment. As illustrated in FIG. 5, in the third embodiment, a configuration in which a semiconductor device 100B includes a third organic insulating film 26 and a second redistribution layer 28, which is different from the first embodiment and the second embodiment described above, will be described.

In the semiconductor device 100B of the third embodiment, the third organic insulating film 26 (third insulating film) is provided between the first organic insulating film 16 and the second organic insulating film 19, and a third opening 27 is provided in a region overlapping at least a part of the first redistribution layer 18. The second redistribution layer 28 is provided on the third organic insulating film 26. More specifically, the second redistribution layer 28 is provided between the first redistribution layer 18 and the bump 21, and is electrically connected to the first redistribution layer 18 via the third opening 27. In addition, the second organic insulating film 19 is provided on the third organic insulating film 26 to cover the second redistribution layer 28. The second opening 20 of the second organic insulating film 19 is provided in a region overlapping at least a part of the second redistribution layer 28.

A width R3 of the third opening 27 of the third organic insulating film 26 in the X-axis direction Dx is larger than the width R2 of the second opening 20 of the second organic insulating film 19 in the X-axis direction Dx. In addition, the width R3 of the third opening 27 of the third organic insulating film 26 in the X-axis direction Dx is larger than the width R1 of the first opening 17 of the first organic insulating film 16 in the X-axis direction Dx. Further, as in the first embodiment and the second embodiment, the width R1 of the first opening 17 of the first organic insulating film 16 in the X-axis direction Dx is larger than the width R2 of the second opening 20 of the second organic insulating film 19 in the X-axis direction Dx.

That is, the third opening 27 is arranged between the second opening 20 and the first opening 17 in the direction perpendicular to the semiconductor substrate 1, and the width R3 of the third opening 27 is larger than the width R1 of the first opening 17 and the width R2 of the second opening 20.

In the present embodiment, the stress transmitted from the bump 21 to the second redistribution layer 28 is dispersed in the region of the second redistribution layer 28 overlapping the second opening 20. That is, the concentration of stress on the outer edge side of the second redistribution layer 28 (a portion of the second redistribution layer 28 in contact with the inner peripheral surface of the third organic insulating film 26) is suppressed. Since the concentration of stress on the outer edge side of the second redistribution layer 28 is suppressed, the stress transmitted from the second redistribution layer 28 to the first redistribution layer 18 is dispersed in the region overlapping the first opening 17. That is, the concentration of stress on the outer edge side of the first redistribution layer 18 (the portion of the first redistribution layer 18 in contact with the inner peripheral surface of the first organic insulating film 16) is suppressed. As a result, in the third embodiment as well, it is possible to suppress thermal stress applied to the mesa structure of the transistor BT from the bump 21 via the second redistribution layer 28 and the first redistribution layer 18.

In this case, even in the configuration in which the three or more layered organic insulating films each having the opening are provided to cover the transistor BT, the width R1 of the first opening 17 of the first organic insulating film 16 provided at a position near the transistor BT in the direction perpendicular to the semiconductor substrate 1 is formed to be larger than the width R2 of the second opening 20 of the second organic insulating film 19 provided at a position farthest from the transistor BT, thereby suppressing thermal stress applied from the bump 21 to the mesa structure of the transistor BT. In other words, the third opening 27 of the second redistribution layer 28 is not limited to the configuration in which the width R3 is larger than the width R1 of the first opening 17 and the width R2 of the second opening 20, and the third opening 27 can be made more flexible.

### Modification of Third Embodiment

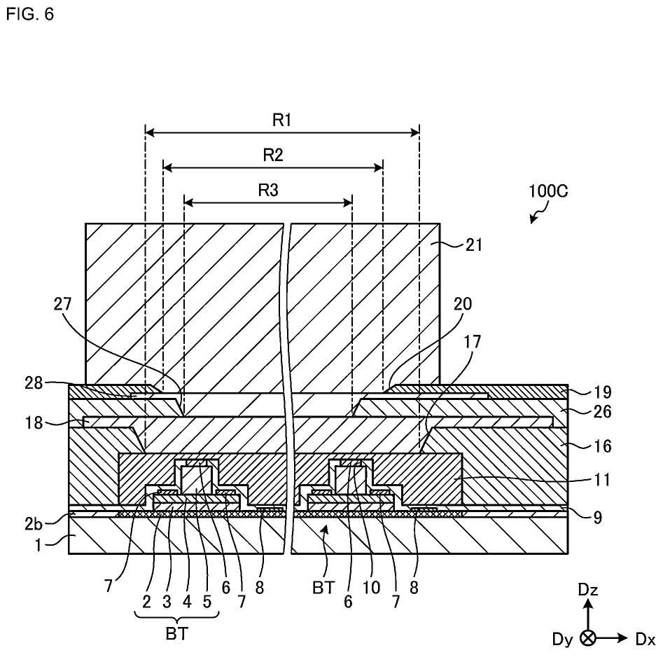

FIG. 6 is an explanatory view of a semiconductor device according to a modification of the third embodiment. As illustrated in FIG. 6, in a semiconductor device 100C according to the modification of the third embodiment, a configuration in which the width R3 of the third opening 27 is formed to be smaller than the width R1 of the first opening 17 and the width R2 of the second opening 20, which is different from the third embodiment described above, will be explained.

The width R3 of the third opening 27 of the third organic insulating film 26 in the X-axis direction Dx is smaller than the width R2 of the second opening 20 of the second organic insulating film 19 in the X-axis direction Dx. In addition, the width R3 of the third opening 27 of the third organic insulating film 26 in the X-axis direction Dx is smaller than the width R1 of the first opening 17 of the first organic insulating film 16 in the X-axis direction Dx. Further, as in the first embodiment and the second embodiment, the width R1 of the first opening 17 of the first organic insulating film 16 in the X-axis direction Dx is larger than the width R2 of the second opening 20 of the second organic insulating film 19 in the X-axis direction Dx.

That is, the third opening 27 is arranged between the second opening 20 and the first opening 17 in the direction perpendicular to the semiconductor substrate 1, and the width R3 of the third opening 27 is smaller than the width R1 of the first opening 17 and the width R2 of the second opening 20.

In the present embodiment, the stress transmitted from the bump 21 to the second redistribution layer 28 is concentrated on the outer edge side of the second redistribution layer 28 (the portion of the second redistribution layer 28 in contact with the inner peripheral surface of the third organic insulating film 26). Even when the stress is concentrated on the outer edge side of the second redistribution layer 28 (the portion of the second redistribution layer 28 in contact with the inner peripheral surface of the third organic insulating film 26), the stress transmitted from the second redistribution layer 28 to the first redistribution layer 18 is dispersed in a region overlapping the first opening 17. That is, even in the configuration in which the width R3 of the third opening 27 is formed to be small, the concentration of stress on the outer edge side of the first redistribution layer 18 (the portion of the first redistribution layer 18 in contact with the inner peripheral surface of the first organic insulating film 16) is suppressed. As a result, in the present modification as well, it is possible to suppress thermal stress applied to the mesa structure of the transistor BT from the bump 21 via the second redistribution layer 28 and the first redistribution layer 18.

Note that the width R3 of the third opening 27 is not limited to a configuration of being smaller than the width R1 of the first opening 17 and the width R2 of the second opening 20, and may be of a size between the width R1 of the first opening 17 and the width R2 of the second opening 20. That is, the width R3 of the third opening 27 may be larger than the width R2 of the second opening 20, and the width R1 of the first opening 17 may be larger than the width R3 of the third opening 27.

### Method of Manufacturing Semiconductor Device

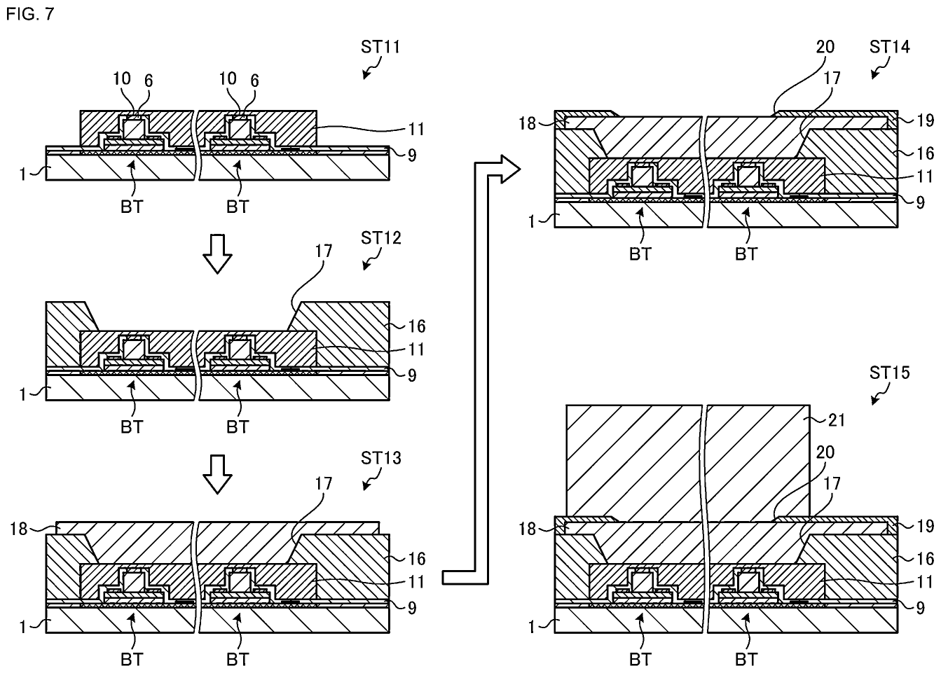

FIG. 7 is an explanatory view for explaining a manufacturing process of a semiconductor device. As illustrated in FIG. 7, a plurality of transistors BT and the insulating films are provided on the semiconductor substrate 1, and the emitter wiring 11 is formed to cover the plurality of transistors BT and the insulating films (step ST11). The emitter wiring 11 is provided to cover the inorganic insulating film 9 and the emitter opening 10, and is in contact with the emitter electrode 6 of the plurality of transistors BT in the emitter opening 10. The emitter wiring 11 is made of a metal material having good conductivity.

Next, the first organic insulating film 16 is formed to cover the emitter wiring 11, and the first opening 17 is provided in a region overlapping the emitter wiring 11 (step ST12). The first opening 17 is formed by patterning the first organic insulating film 16 by photolithography, etching, and the like.

Next, the first redistribution layer 18 is provided on the first organic insulating film 16 to cover the first opening 17 of the first organic insulating film 16 (step ST13). The first redistribution layer 18 is in contact with the emitter wiring 11 at the bottom of the first opening 17.

Next, the second organic insulating film 19 is formed to cover the first redistribution layer 18 and the first organic insulating film 16, and the second opening 20 is formed in a region of the second organic insulating film 19 that overlaps a part of the first redistribution layer 18 (step ST14). The width of the second opening 20 of the second organic insulating film 19 is formed to be smaller than the width of the first opening 17 of the first organic insulating film 16.

Next, the bump 21 is formed on the second organic insulating film 19 and the first redistribution layer 18 (step ST15). The bump 21 may be formed by any process, but is formed by plating, for example. In this case, a power supply film (not illustrated) is provided on the second organic insulating film 19 and the first redistribution layer 18 as a base layer of the bump 21.

Note that the manufacturing process illustrated in FIG. 7 is merely an example, and can be appropriately changed. For example, the redistribution layer and the organic insulating film may be formed in a plurality of layers by repeating the steps ST12 and ST13.

In addition, in each of the above-described embodiments, the semiconductor device in which one bump 21 is provided to overlap the plurality of transistors BT has been described as an example, but the disclosure is not limited thereto. A semiconductor device in which one bump is formed to overlap one transistor may be used. Further, although the pillar bump is described as an example of the bump, for example, a solder bump or a stud bump may be used in addition to the pillar bump.

In addition, the materials, thicknesses, dimensions, and the like of the components described in the embodiments are merely examples, and may be changed as appropriate. The materials and thicknesses of the sub-collector layer 2, the collector layer 3, the base layer 4, the emitter layer 5, and various wirings may be changed as appropriate.

Note that the above-described embodiments are intended to facilitate understanding of the present disclosure, and are not intended to limit the present disclosure. The present disclosure can be modified or improved without departing from the gist thereof, and the present disclosure includes equivalents thereof.

What is claimed is:

1. A semiconductor device comprising:
a semiconductor substrate;
at least one transistor on the semiconductor substrate and including a plurality of semiconductor layers;
a wiring on the transistor;
a first insulating film including a first opening in a region overlapping the transistor and the wiring in plan view in a first direction perpendicular to the semiconductor substrate;
a first redistribution layer on the first insulating film, overlapping the at least one transistor in the first direction in plan view, and electrically connected to the wiring via the first opening;
a second insulating film covering the first redistribution layer and the first insulating film, and including a second opening in a region overlapping at least a part of the first redistribution layer in the first direction in plan view; and
a bump electrically connected to the first redistribution layer via the second opening,
wherein a width of the first opening of the first insulating film in a second direction parallel to the semiconductor substrate is larger than a width of the second opening of the second insulating film in the second direction.

2. The semiconductor device according to claim 1, wherein
the transistor has a collector electrode connected to a collector layer, and
an overlapping organic insulating film is between the collector electrode and the wiring and the first redistribution layer on the transistor in the first direction.

3. The semiconductor device according to claim 1, further comprising:
a third insulating film between the first insulating film and the second insulating film, and including a third opening in a region overlapping at least a part of the first redistribution layer in the first direction in plan view; and
a second redistribution layer between the first redistribution layer and the bump and electrically connected to the first redistribution layer via the third opening.

4. The semiconductor device according to claim 1, wherein
the at least one transistor includes transistors arranged side by side in the second direction, and
the bump and the first opening of the first insulating film are over a plurality of the transistors.

5. The semiconductor device according to claim 2, further comprising:
a third insulating film between the first insulating film and the second insulating film, and including a third opening in a region overlapping at least a part of the first redistribution layer in the first direction in plan view; and
a second redistribution layer between the first redistribution layer and the bump and electrically connected to the first redistribution layer via the third opening.

6. The semiconductor device according to claim 2, wherein
the at least one transistor includes transistors arranged side by side in the second direction, and
the bump and the first opening of the first insulating film are over a plurality of the transistors.

7. The semiconductor device according to claim 3, wherein
the at least one transistor includes transistors arranged side by side in the second direction, and
the bump and the first opening of the first insulating film are over a plurality of the transistors.

8. The semiconductor device according to claim 5, wherein
the at least one transistor includes transistors arranged side by side in the second direction, and
the bump and the first opening of the first insulating film are over a plurality of the transistors.
